(19) United States
(12) Patent Application Publication
(10) Pub. No.: US 2026/0126488 A1
(43) Pub. Date: May 7, 2026

(54) MOTOR DRIVING SYSTEM AND METHOD FOR DIAGNOSING FAULT THEREOF

(71) Applicants: HYUNDAI MOTOR COMPANY, SEOUL (KR); KIA CORPORATION, SEOUL (KR)

(72) Inventors: Young Su Ko, Hwaseong-si (KR); Jun Mo An, Hwaseong-si (KR); Hyun Woo Paik, Hwaseong-si (KR)

(73) Assignees: HYUNDAI MOTOR COMPANY, SEOUL (KR); KIA CORPORATION, SEOUL (KR)

(21) Appl. No.: 19/229,504

(22) Filed: Jun. 5, 2025

(30) Foreign Application Priority Data
Nov. 6, 2024 (KR) 10-2024-0156396

(51) Int. Cl. G01R 31/34; H02M 7/537; H02P 3/08; H02P 25/18; H02P 27/06

(52) U.S. Cl. CPC G01R 31/34; H02M 7/537; H02P 3/08; H02P 25/18; H02P 27/06; H02P 2209/11

(57) ABSTRACT

A motor driving system and a method for diagnosing a fault thereof are provided. The motor driving system includes a driving unit including a motor, and a first inverter and a second inverter connected to both ends of each of multiple windings, respectively, and a control unit configured to control outputs of the first inverter and the second inverter based on a zero-sequence current command and further configured to diagnose a fault in the driving unit based on a phase current flowing in each of the multiple windings as a result of the control.

### CROSS-REFERENCE TO RELATED APPLICATION(S)

This application claims priority under 35 U.S.C. 119 to Korean Patent Application No. 10-2024-0156396, filed on Nov. 6, 2024, in the Korean Intellectual Property Office, the disclosure of which is herein incorporated by reference in its entirety.

### TECHNICAL FIELD

The present disclosure relates to a motor driving system for diagnosing a fault by using a zero-sequence current command and a method for diagnosing a fault thereof.

### BACKGROUND

In the case of windings of phases in a motor, one end of each winding is connected to one inverter, and the other ends of the windings are connected to each other to form a Y-connection.

During driving of the motor, switching elements in the inverter are turned on and off by pulse width modulation control to apply a line-to-line voltage to the Y-connected windings of the motor, thereby generating alternating current and producing torque.

Furthermore, instead of forming a Y-connection with the other end of the motor, two inverters may be connected to opposite ends of the motor, respectively, and the output of the motor may be increased by driving the motor through the two inverters.

Diagnosis of a fault in a motor-driven system including the motor and the inverter may be performed by applying a current command for fault diagnosis and identifying the value of a phase current (e.g., actually) flowing in each winding in response to the current command.

The foregoing is intended to aid in providing background of the present disclosure, and is not intended to provide that the present disclosure is prior art.

### SUMMARY

The present disclosure provides a motor driving system capable of diagnosing a fault while (e.g., substantially) preventing vibration and noise caused by (e.g., instantaneous) torque, and a method for diagnosing a fault thereof.

The present disclosure may not be limited to the technical subjects provided herein, as other technical subjects which are not mentioned may be understood from the following descriptions.

In an example embodiment, a motor driving system includes a driving unit including a motor having multiple windings corresponding to multiple phases, a first inverter connected to one end (e.g., a first end) of each of the multiple windings, and a second inverter connected to the other end (e.g., a second end) of each of the multiple windings, and a control unit configured to control outputs of the first inverter and the second inverter based on a zero-sequence current command, causing phase currents having the same magnitude and phase to flow in the multiple windings, and diagnose a fault in the driving unit based on the phase currents flowing in the multiple windings as a result of the control.

In an example embodiment, a method for controlling a motor driving system is provided. The method for diagnosing a fault in a driving unit includes a motor having multiple windings corresponding to multiple phases, a first inverter connected to one end of each of the multiple windings, and a second inverter connected to the other end of each of the multiple windings. The method also includes controlling outputs of the first inverter and the second inverter based on a zero-sequence current command, which causes phase currents having the same magnitude and phase to flow in the multiple windings, and diagnosing a fault in the driving unit based on the phase currents flowing in the multiple windings as a result of the control.

According to example embodiments of the present disclosure, it may be possible to diagnose whether a fault has occurred in the motor driving system, even while the motor is being driven, and furthermore, it may be possible to identify (e.g., specify) a phase in which the fault has occurred among phases of the motor.

Furthermore, according to an example embodiment, by diagnosing, based on the zero-sequence current command, whether a fault has occurred in the motor driving system, it is possible to (e.g., substantially) prevent vibration and noise caused by instantaneous torque during the fault diagnosis process.

The present disclosure may not be limited to the above-mentioned improvements, and other improvements which are not mentioned may be understood from the descriptions herein.

### BRIEF DESCRIPTION OF THE DRAWINGS

The aspects and features the present disclosure may be provided from the description and accompanying drawings herein, in which:

FIGS. 1 and 2 provide a configuration of a motor driving system according to an example embodiment of the present disclosure.

FIG. 3 provides a configuration of a control unit according to an example embodiment of the present disclosure.

FIG. 4 provides a graph of a phase current and torque resulting from the fault diagnosis of a motor driving system according to an example embodiment of the present disclosure.

FIG. 5 is a flowchart providing a method for diagnosing a fault in a motor drive system according to an example embodiment of the present disclosure.

### DETAILED DESCRIPTION

Example embodiments of the disclosure are provided herein. The example embodiments according to the present disclosure may be provided in various forms, and the present disclosure should not be limited to the example embodiments described herein.

Various changes and modifications may be made to the example embodiments according to the present disclosure, and therefore example embodiments are provided illustrated in the drawings and described in the specification or application. However, it should be understood that embodiments according to the concept of the present disclosure are not limited to the particular disclosed embodiments, but the present disclosure includes (e.g., all) modifications, equivalents, and alternatives falling within the spirit and scope of the present disclosure.

Herein, example embodiments set forth herein will be described with reference to the drawings, and the same or similar elements are given the same and similar reference numerals regardless of figure numbers, so duplicate descriptions thereof may be omitted.

In the following description of the example embodiments, the term “predetermined” may imply a parameter that is used in a process or algorithm, and the parameter may have a (e.g., previously) determined numerical value. The numerical value of the parameter may be set at the beginning of the process or algorithm or during an interval when the process or algorithm is performed.

The terms “module” and “unit” used for the elements in the description are given or interchangeably used in consideration of the specification, and may not have distinct meanings or roles by themselves.

In describing the example embodiments set forth herein, a detailed description of functions or configurations incorporated herein may be omitted when the description may make the subject matter of the embodiments set forth herein unclear. In addition, the accompanying drawings are provided for the understanding of the example embodiments herein, and the technical idea of the present disclosure is not limited to the accompanying drawings and may include (e.g., all) modifications, equivalents, or alternatives provided by the present disclosure.

Terms including an ordinal number such as “a first” and “a second” may be used to describe various elements, but the elements are not limited to the terms. The above terms are used for distinguishing one element from other elements.

Where an element is referred to as being “connected” or “coupled” to other elements, the element may be (e.g., directly) connected or coupled to the other elements, but also another element may exist therebetween. Contrarily, in the case where an element is referred to as being “directly connected” or “directly coupled” to any other element, no other element may exist therebetween.

A singular expression may include a plural expression unless they are different in a context.

As used herein, the expression “include” or “have” are intended to include mentioned features, numbers, steps, operations, elements, components, or combinations thereof, and should be construed as not precluding the possible existence or addition of one or more other features, numbers, steps, operations, elements, components, or combinations thereof.

A unit or a control unit included in names of a component such as a motor control unit (MCU) and a hybrid control unit (HCU) is a term used for a controller configured to control a (e.g., specific) function of a vehicle, but may not mean a generic function unit.

A controller may include a communication device configured to communicate with a sensor or another control unit, a memory configured to store an operation system, a logic command, or input/output information, and at least one processor configured to perform determination, calculation, decision or the like which are used (e.g., required) for (e.g., responsible) function controlling.

A motor driving system according to an example embodiment of the present disclosure diagnoses whether there is a fault in motor driving by using a zero-sequence current that does not or may not generate torque, thereby providing a fault diagnosis to be provided (e.g., performed) without generating noise or vibration even during motor driving.

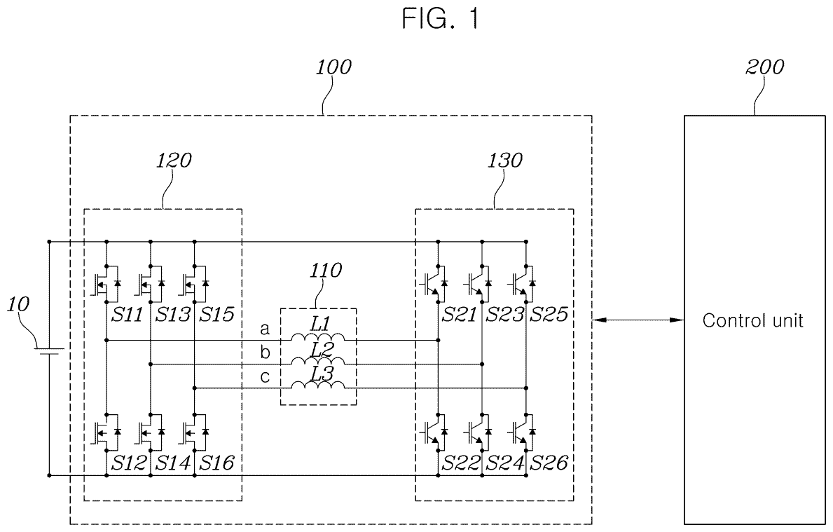

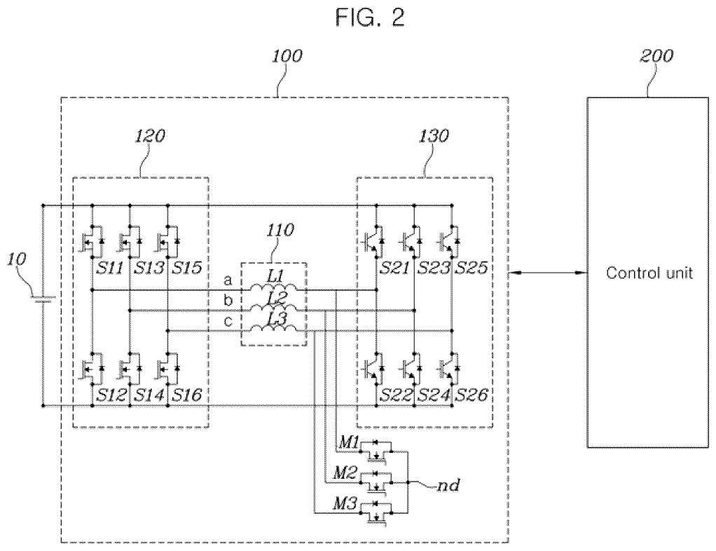

Before describing a fault diagnosis method according to an example embodiment of the present disclosure, a configuration of a motor driving system according to example embodiments of FIGS. 1 and 2.

FIGS. 1 and 2 provide a configuration of a driving unit that may be applied in example embodiments of the present disclosure.

Referring to FIG. 1, a drive unit 100 according to an example embodiment of the present disclosure includes a motor 110, a first inverter 120, and a second inverter 130.

The motor 110 has multiple (e.g., a plurality of) windings L1, L2, and L3 corresponding to multiple phases a, b, and c, respectively, and the first inverter 120 is connected to one end of each of the multiple windings L1, L2, and L3, and the second inverter 130 is connected to the other end of each of the multiple windings L1, L2, and L3.

In an example embodiment, the first inverter 120 may include multiple first switching elements S11-S16 connected to one end of each of the multiple windings L1, L2, and L3, and the second inverter 130 may include multiple second switching elements S21-S26 connected to the other end of each of the multiple windings L1, L2, and L3.

The first inverter 120 may include multiple legs S11-S12, S13-S14, and S15-S16 to which a direct current voltage from a battery 10 is applied, and the legs S11-S12, S13-S14, and S15-S16 may correspond to and be electrically connected to the multiple phases a, b, and c of the motor 110, respectively. Connection nodes of two switching elements connected to each of the legs S11-S12, S13-S14, and S15-S16 included in the first inverter 120 may be connected to one end of a winding of one corresponding phase of the motor 110 such that alternating current power corresponding to the corresponding phase of the multiple phases is input and output.

Similarly, the second inverter 130 may include multiple legs S21-S22, S23-S24, and S25-S26 to which a direct current voltage from the battery 10 is applied. Connection nodes of two switching elements connected to each of the legs S21-S22, S23-S24, and S25-S26 included in the second inverter 130 may be connected to one end of a winding of one corresponding phase of the motor 110 such that alternating current power corresponding to the corresponding phase of the multiple phases is input and output.

The first inverter 120 and the second inverter 130 may convert the DC voltage of the battery 10 to an alternating voltage through switching operations of the switching elements S11-S16 and S21-S26 included therein, respectively, and may apply the converted alternating voltage to the motor 110 to drive the motor 110. The switching elements of the legs S11-S12, S13-S14, S15-S16, S21-S22, S23-S24, and S25-S26 included in the first inverter 120 and the second inverter 130 may be divided into top switching elements S11, S13, S15, S21, S23, and S25 and bottom switching elements S12, S14, S16, S22, S24, and S26. During the switching operations of the first inverter 120 and the second inverter 130, the top switching elements S11, S13, S15, S21, S23, and S25 and the bottom switching elements S12, S14, S16, S22, S24, and S26 are turned on/off complementarily.

In an example embodiment, the switching elements S11-S16 and S21-S26 may be provided as elements capable of performing switching operations, such as an insulated gate bipolar transistor (IGBT) or a metal oxide semiconductor field effect transistor (MOSFET). In addition, the first inverter 120 and the second inverter 130 may be provided as different (e.g., types of) switching elements. For example, the first inverter 120 may be provided as an MOSFET and the second inverter 130 may be provided as an IGBT.

In the driving unit 100 provided herein, both ends of each of the multiple windings L1, L2, and L3 included in the motor 110 are not connected, and, unlike the case where one or the other end of the motor 110 is connected, a zero-sequence quadrature current may flow. Here, the zero-sequence current is a current on an axis orthogonal to the d-axis and the q-axis in the d-q-axis synchronous coordinate system in three-dimensional space, and the zero-sequence current has a characteristic that phase currents flowing through phases have the same phase and magnitude and do not generate torque.

Referring to FIG. 2, the driving unit 100 may further include multiple changeover switches M1, M2, and M3.

One-side end of each of the multiple changeover switches M1, M2, and M3 may be connected to the other-side ends of the corresponding winding among the multiple windings L1, L2, L3, and the other-side ends of changeover switches M1, M2, and M3 may be connected to each other to form a node nd.

The multiple changeover switches M1, M2, and M3 may electrically connect or disconnect the motor 110 and the second inverter 130 depending on the switching state, and, like the switching elements S11-S16 and S21-S26 of the first inverter 120 and the second inverter 130, may be provided as elements capable of performing switching operations, such as IGBTs or MOSFETs.

For example, when the switching state of the multiple changeover switches M1, M2, and M3 is a turn-on state, the node nd may form the neutral point of the motor 110, and accordingly, the second inverter 130 may be electrically disconnected from the motor 110. In an example embodiment, the motor 110 may be driven by the first inverter 120 alone, and such a driving mode may be represented as a “closed-end winding (CEW) mode”.

On the other hand, when the switching state of the multiple changeover switches M1, M2, and M3 is a turn-off state, the node nd does not form the neutral point of the motor 110, and accordingly, the second inverter 130 may be electrically connected to the motor 110. In an example embodiment, the motor 110 may be driven by the first inverter 120 and the second inverter 130, and such a driving mode may be represented as an “open-end winding (OEW) mode”.

Thus, in the structure of the driving unit 100 in FIG. 2, the multiple changeover switches M1, M2, and M3 are turned on to allow a zero-sequence current to flow while the motor 110 and the second inverter 130 are electrically connected (e.g., to each other) (e.g., in the OEW mode).

A control unit 200 may drive the motor 110 by controlling the switching state of the first inverter 120 and the second inverter 130, and when the driving unit 100 is provided as in FIG. 2, may control a driving mode as an open-end winding mode or a closed-end winding mode by controlling the switching state of the multiple changeover switches M1, M2, and M3.

For example, the control unit 200 may drive the motor 110 by controlling the switching state of each of the switching elements S11-S16 and S21-S26 included in the first inverter 120 and the second inverter 130 as a turn-on or turn-off state based on a (e.g., required) output of the motor 110, a voltage of the battery 10, a phase current of the motor 110, and a motor angle.

Furthermore, the control unit 200 may control the driving mode of the motor 110 as a CEW mode or an OEW mode based on the mode switching criteria based on the efficiency map, and the (e.g., required) torque and inverse flux of the motor 110. In an example embodiment, the efficiency map may be derived based on the result of measuring, through a test, the losses of the motor 110 according to the rotational speed and torque of the motor 110 in each driving mode for each voltage of the battery 10, and the mode switching criteria may correspond to the boundary between the high-efficiency region of the CEW mode and the high-efficiency region of the OEW mode.

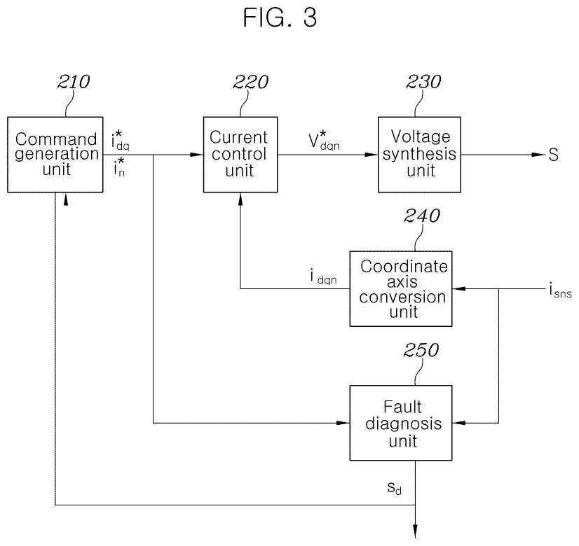

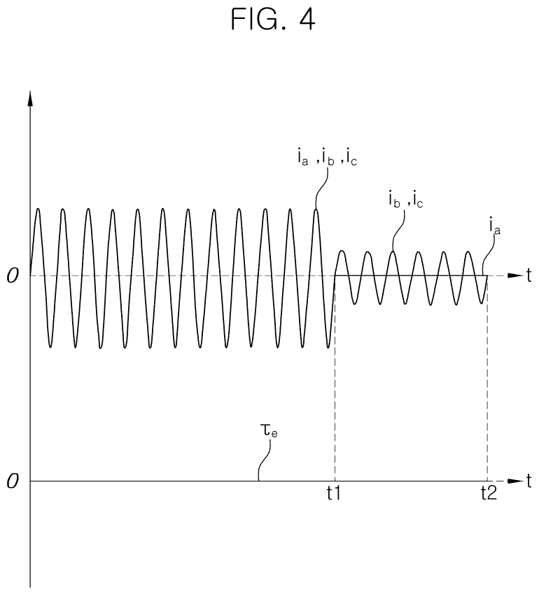

The control unit 200 may (e.g., not only) drive the motor 110 or control the driving mode of the motor 110 as described herein, but also may diagnose whether a fault has occurred in the driving unit 100, as described herein with reference to at least FIGS. 3 and 4.

FIG. 3 provides a configuration of a control unit according to an example embodiment of the present disclosure. FIG. 4 provides a graph of a phase current and torque resulting from the fault diagnosis of a motor driving system according to an example embodiment of the present disclosure.

Referring to FIG. 3, the control unit 200 may control outputs of the first inverter 120 and the second inverter 130 based on a zero-sequence current command that causes phase currents having the same (e.g., or substantially the same) magnitude and phase to flow in the multiple windings L1, L2, and L3 of the motor 110, and may diagnose a fault in the driving unit 100 based on the phase currents according to the outputs of the first inverter 120 and the second inverter 130, which may be the result of the control. The control unit 200 may include a command generation unit 210, a current control unit 220, a voltage synthesis unit 230, a coordinate axis conversion unit 240, and a fault diagnosis unit 250.

The command generation unit 210 may generate a zero-sequence current command iₙ* and a dq-axis current command i_{dq}* for diagnosing a fault in the driving unit 100, and may apply the commands to the current control unit 220. In an example embodiment, the zero-sequence current command iₙ* is a current command that causes the phase currents of the multiple phases a, b, and c to have the same magnitude and phase, and may cause each of the phase currents to have a sinusoidal shape. Furthermore, the command generation unit 210 may generate a dq-axis current command i_{dq}* that sets the value of the DQ-axis current to “0”, and may control the dq-axis current to be “0” while the fault diagnosis is performed by application of the zero-sequence current command iₙ*.

The application of the zero-sequence current command iₙ* and the dq-axis current command i_{dq}* for fault diagnosis may be performed in a state in which both ends of the motor 110 are electrically connected to the first inverter 120 and the second inverter 130, respectively, as in the OEW mode, in the structure in FIG. 1 or FIG. 2. In contrast, when either or both ends of the motor 110 is connected and a neutral point is formed, fault diagnosis may be performed based on the dq-axis current command i_{dq}* which causes dq-axis currents to be sinusoidal waves having a 90-degree phase difference therebetween, rather than using the zero-sequence current command iₙ*.

The current control unit 220 may generate a voltage command V_{dqn}* based on the zero-sequence current command in* and a current value i_{dqn} of the motor 110 applied by the command generation unit 210. In an example embodiment, the coordinate axis conversion unit 240 may convert a measured value iₛₙₛ of a phase current flowing in the windings L1, L2, and L3 of the motor 110 into a value i_{dqn} in the synchronous coordinate system of the dqn axis and provide the value to the current control unit 220. Furthermore, the measured value iₛₙₛ of the phase currents may be obtained through current sensors provided in the phases a, b, and c.

The voltage synthesis unit 230 performs voltage synthesis based on the voltage command V_{dqn} ^{*}, which has been output from the current control unit 220, to output a synthesized voltage S. Through this, the outputs of the first inverter 120 and the second inverter 130 are controlled.

In this process, pulse-width modulation (PWM) control may be performed, and in a “normal” state, the outputs of the first inverter 120 and the second inverter 130 are controlled to satisfy the current commands iₙ* and i_{dq} ^{*}.

The fault diagnosis unit 250 may diagnose a fault in the driving unit 100 based on the zero-sequence current command iₙ* and the corresponding measured value iₛₙₛ of the phase current, and may output a signal S_{d} corresponding to the result of the diagnosis. In an example embodiment, the fault in the driving unit 100 may include, for example, a fault due to a break in the winding L1, L2, or L3 included in the motor 110, a fault due to damage of the switching elements S11-S16 and S21-S26 included in the first inverter 120 and the second inverter 130, a break in a cable connecting the motor 110 to the first inverter 120 and the second inverter 130, and the like.

In an example embodiment, the fault diagnosis unit 250 may diagnose whether a fault has occurred in the drive unit 100, based on the error between the value of the zero-sequence current command in* and the corresponding measured value iₛₙₛ of the phase current. For example, when the error between the value of the zero-sequence current command iₙ* and the measured value iₛₙₛ of the phase current flowing in at least one of the multiple phases a, b, and c exceeds a predetermined tolerance, or when the state where the tolerance is exceeded continues for a (e.g., certain) period of time, the fault diagnosis unit 250 may determine that a fault has occurred in the driving unit 100. In particular, when the measured value iₛₙₛ of the phase current is “0” despite the application of the zero-sequence current command iₙ^{*}, the fault diagnosis unit 250 may diagnose that a break has occurred in the motor 110 or the cable.

Furthermore, the fault diagnosis unit 250 may determine whether a fault has occurred in the driving unit 100, and may also determine which phase among the multiple phases a, b, and c has experienced a fault. The fault diagnosis unit 250 may specify the phase which has experienced a fault. For example, when the error between the measured value of a phase current in phase a and the value of the zero-sequence current command iₙ* exceeds the tolerance, the fault diagnosis unit 250 may diagnose that a fault has occurred in phase a.

When, as a result of the diagnosis, it is determined that a fault has occurred in the driving unit 100, the driving of the motor 110 may be interrupted. Control corresponding to the fault diagnosis may be performed, for example, by the command generation unit 210 stopping the application of the current command when the control signal s_{d} corresponding to the diagnosis result is output.

The fault diagnosis process may be performed before the motor 110 is started (e.g., to drive), and also in a state in which the rotational speed of the motor 110 exceeds “0”, such as during the traveling of a vehicle through the driving force of the motor 110. In an example embodiment, since the fault diagnosis is performed by applying the zero-sequence current command iₙ* while the value of the dq axis current command i_{dq}* is set to “0”, it is possible to diagnose a fault in the driving unit 100 in a state in which there is no generation of instantaneous torque as well as average torque, thereby preventing the generation of torque or the generation of noise and vibration during the fault diagnosis process.

In this regard, FIG. 4 provides a graph of phase currents iₐ, i_{b}, and i_{c} and the torque τₑ of the motor 110 when fault diagnosis is performed during interval 0-t2 on the time axis (t). In the interval from 0 to t1, the phase currents iₐ, i_{b}, and i_{c} have the same phase and magnitude according to the zero-sequence current command iₙ*. In an example embodiment, the fault diagnosis unit 250 may determine that the driving unit 100 is in a “normal” state.

In the interval from t1 to t2, a change occurs in the waveform of the phase currents iₐ, i_{b}, and i_{c}, so that the amplitudes of the phase currents i_{b} and i_{c} in the phases b and c decrease, and the value of the phase current iₐ in the phase a is “0”. In an example embodiment, the fault diagnosis unit 250 may determine that a fault has occurred in the driving unit 100, and may determine that a fault has occurred in the phase a where the value of the phase current iₐ is “0”.

The value of the torque τₑ of the motor 110 is maintained at “0” in the (e.g., entire) interval 0-t2, including the interval 0-t1 in which the driving unit 100 is determined to be in a “normal” state and the interval t1-t2 in which the driving unit 100 is determined to have a fault. No instantaneous torque is generated during the (e.g., entire) fault diagnosis process, and accordingly, no noise and vibration are generated during the fault diagnosis process.

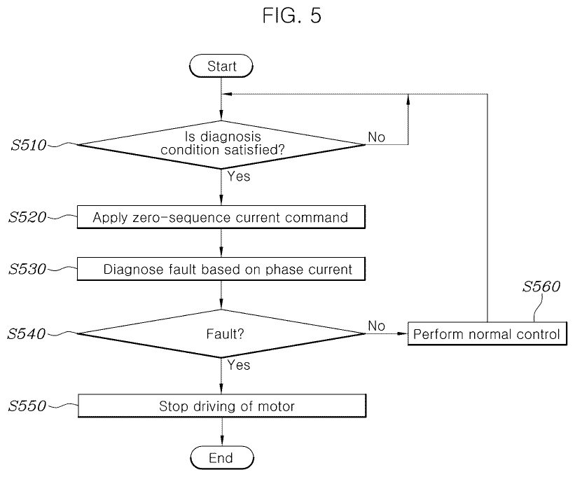

Hereinafter, a method for diagnosing a fault in a motor drive system according to an example embodiment will be provided with reference to FIG. 5.

FIG. 5 is a flowchart providing a method for diagnosing a fault in a motor drive system according to an example embodiment of the present disclosure.

Referring to FIG. 5, the control unit 200 may determine whether a diagnostic condition is satisfied (S510). When the diagnostic condition is satisfied (Yes in S510), the control unit 200 may apply a zero-sequence current command to diagnose a fault (S520). In an example embodiment, the diagnostic condition may be satisfied regardless of whether the motor 110 is being driven. For example, in the event of an abnormality in the power supply, such as a fault in a switching mode power supply (SMPS), during the driving of the motor 110, the condition may be satisfied when the driving of the motor 110 is started.

Thereafter, the control unit 200 may diagnose a fault in the driving unit 100 based on the value of a phase current flowing in each phase in response to the application of the zero-sequence current command (S530). When a fault has occurred (Yes in S540), the control unit 200 may output a signal corresponding to the fault occurrence, and may stop driving the motor 110 (S550)). When, as a result of the diagnosis, it is determined that the driving unit 100 is in a “normal” state (No in S540), normal control is performed (S560). When the diagnosis condition is satisfied again during the normal control (Yes in S510), the fault diagnosis process using the zero-sequence current command may be performed again.

According to example embodiments of the present disclosure provided herein, it is possible to diagnose whether a fault has occurred in the motor driving system, even while the motor is being driven, and furthermore, may provide a phase in which the fault has occurred among phases of the motor.

Furthermore, according to an example embodiment, by diagnosing, based on the zero-sequence current command, whether a fault has occurred in the motor driving system, it is possible to prevent or minimize vibration and noise caused by instantaneous torque during the fault diagnosis process.

Although the present disclosure is provided in conjunction with example embodiments thereof, various improvements and modifications may be made to the present disclosure without departing from the present disclosure and the claims provided herein.

What is claimed is:

1. A motor driving system including:
a driving unit including a motor having multiple windings corresponding to multiple phases, a first inverter connected to a first end of each of the multiple windings, and a second inverter connected to a second end of each of the multiple windings; and
a control unit configured to control outputs of the first inverter and the second inverter based on a zero-sequence current command, causing phase currents having the same magnitude and phase to flow in the multiple windings, and the control unit further configured to diagnose a fault in the driving unit based on the phase currents flowing in the multiple windings as a result of the control.

2. The motor driving system of claim 1, wherein the control unit is configured to maintain values of a d-axis current command and a q-axis current command at “0” while controlling the outputs of the first inverter and the second inverter based on the zero-sequence current command.

3. The motor driving system of claim 1, wherein the zero-sequence current command has a sinusoidal wave.

4. The motor driving system of claim 1, wherein the control unit is configured to control the outputs of the first inverter and the second inverter based on the zero-sequence current command with a rotational speed of the motor exceeding “0”.

5. The motor driving system of claim 1, wherein the control unit is configured to control the outputs of the first inverter and the second inverter based on the zero-sequence current command when driving of the motor is started.

6. The motor driving system of claim 1, wherein the control unit is configured to diagnose that a fault has occurred in the driving unit, when an error between a value of a phase current flowing in at least one of the multiple phases and a value of the zero-sequence current command exceeds a predetermined tolerance.

7. The motor driving system of claim 6, wherein the control unit is configured to diagnose that a fault has occurred in a phase corresponding to a winding where a phase current, with the error exceeding the predetermined tolerance, flows.

8. The motor driving system of claim 1, wherein the driving unit further includes multiple changeover switches, each changeover switch having a first end connected to the second end of a corresponding winding among the multiple windings, each changeover switch having a second end, wherein the second ends of the changeover switches are interconnected to form a node, and
wherein the control unit is configured to control switching states of the multiple changeover switches to electrically connect or disconnect the motor and the second inverter.

9. The motor driving system of claim 8, wherein the control unit is configured to control the outputs of the first inverter and the second inverter based on the zero-sequence current command with the multiple changeover switches turned off and the second inverter electrically connected to the multiple windings.

10. The motor driving system of claim 1, wherein the control unit is configured to stop driving of the motor when a fault is diagnosed to have occurred in the driving unit.

11. A method for diagnosing a fault in a motor driving system having a driving unit, the driving unit includes a motor having multiple windings corresponding to multiple phases, a first inverter connected to a first end of each of the multiple windings, and a second inverter connected to a second end of each of the multiple windings, the method including:
controlling outputs of the first inverter and the second inverter based on a zero-sequence current command, causing phase currents having the same magnitude and phase to flow in the multiple windings; and
diagnosing a fault in the driving unit based on the phase currents flowing in the multiple windings as a result of the control.

12. The method of claim 11, wherein the controlling of the outputs includes providing values of a d-axis current command and a q-axis current command at “0” while controlling the outputs of the first inverter and the second inverter based on the zero-sequence current command.

13. The method of claim 11, wherein the zero-sequence current command provides each of the phase currents flowing in the multiple windings to have a sinusoidal shape.

14. The method of claim 11, wherein the controlling of the outputs includes controlling the outputs of the first inverter and the second inverter based on the zero-sequence current command with a rotational speed of the motor exceeding “0”.

15. The method of claim 11, wherein the controlling of the outputs includes controlling the outputs of the first inverter and the second inverter based on the zero-sequence current command before driving of the motor is started.

16. The method of claim 11, wherein the diagnosing of the fault includes diagnosing that a fault has occurred in the driving unit, when an error between a value of a phase current flowing in at least one of the multiple phases and a value of the zero-sequence current command exceeds a predetermined tolerance.

17. The method of claim 16, wherein the diagnosing of the fault includes diagnosing that a fault has occurred in a phase corresponding to a winding where a phase current, with the error exceeding the predetermined tolerance, flows.

18. The method of claim 11, wherein the driving unit further includes multiple changeover switches, each multiple changeover switch has a first end connected to the second end of a corresponding winding among the multiple windings, each changeover switch having a second end, wherein the second ends of the changeover switches are interconnected to form a node, and
wherein the method further includes controlling switching states of the multiple changeover switches to electrically connect or disconnect the motor and the second inverter.

19. The method of claim 18, wherein the controlling of the outputs includes controlling the outputs of the first inverter and the second inverter based on the zero-sequence current command with the second inverter electrically connected to the multiple windings.

20. The method of claim 11, further comprising stopping the driving of the motor when a fault is diagnosed to have occurred in the driving unit.
